(19) United States
(12) Patent Application Publication
(10) Pub. No.: US 2008/0061408 A1
(43) Pub. Date: Mar. 13, 2008

(54) INTEGRATED CIRCUIT PACKAGE

(75) Inventors: Felix C. Li, Sunnyvale, CA (US); Carlos Sanchez, Napa, CA (US); Walter Bacharowski, Sunnyvale, CA (US); Willem Johannes Kindt, Berkel En Rodenrijs (NL)

Correspondence Address: BEYER WEAVER LLP, P.O. BOX 70250, OAKLAND, CA, 94612-0250, US

(73) Assignee: NATIONAL SEMICONDUCTOR CORPORATION, Santa Clara, CA (US)

(21) Appl. No.: 11/552,879

(22) Filed: Oct. 25, 2006

Related U.S. Application Data
(60) Provisional application No. 60/825,098, filed on Sep. 8, 2006.

(51) Int. Cl. H01L 23/495

(52) U.S. Cl. 257/666

(57) ABSTRACT

A novel, small outline molded, high voltage, lead frame based integrated circuit package is described. The integrated circuit die has at least one high voltage I/O pad that is electrically connected to an associated high voltage lead/pin in the lead frame. All of the pins of the lead frame that are not high voltage pins have a standard pitch between adjacent pins on the same side of the lead frame that is no more than approximately 0.5 mm. The pitch between each high voltage pin and an adjacent pin is double the standard pitch. The high voltage I/O pad is arranged to handle output signals having voltages of at least 30 volts. In some embodiments, the lead frame is formed from a copper or copper alloy based material and exposed portions of the pins are plated with a lead/tin based solder material.

### CROSS REFERENCE TO RELATED APPLICATIONS

This application claims the benefit of priority under 35 USC 119(e) to U.S. Provisional Patent Application No. 60/825,098, filed Sep. 8, 2006, which is incorporated herein by reference in its entirety for all purposes.

### FIELD OF THE INVENTION

The present invention relates generally to the packaging of integrated circuits. More particularly, the invention relates to an integrated circuit package suitable for use in high voltage and high frequency applications requiring small-outline footprints.

### BACKGROUND OF THE INVENTION

There are a number of conventional processes for packaging integrated circuits. Many packaging techniques use a leadframe that has been stamped or etched from a metal (typically copper) sheet to provide electrical interconnects to external devices. One conventional packaging type is a mini small-outline package (MSOP). MSOPs typically have a package body size of approximately 3 mm by 3 mm and are preferred in many applications where space is at a premium.

MSOPs are dual inline packages (DIPs). That is, the leadframe typically includes an array of contacts that protrude from the sides of the package in the form of two rows of pins, one row being on either side of the package, the pins serving as the electrical interconnects. Typical MSOPs have a total of 8 or 10 pins with a pin pitch (i.e., the pin center to pin center spacing) of 0.5 mm. By way of example, FIG. 3(a)-(c) illustrate one diagrammatic top view and two diagrammatic side views of a standard MSOP package.

The leadframe may also include a die attach pad upon which a die is mounted. After the die is mounted onto the die attach pad, electrical connections (generally in the form of bonding wires) are formed between the bond pads on the die and the contacts on the leadframe. After the die is electrically connected to the leadframe, a molding compound is often used to encapsulate the device. The molding compound protects the die, bonding wires, contacts and contact pins and makes the device easier to handle during subsequent mounting onto a substrate, such as a printed circuit board.

In applications requiring high voltages, such as common mode voltages, it is inevitable that one or more high voltage pins will be adjacent to one or more low voltage pins. Such high voltage applications include signal amplifications, wireless applications, and automotive systems such as engine control or GPS navigation systems. By way of example, in such applications, it is now common for a pin connected to a common mode voltage greater than 30V to be next to a pin carrying a supply voltage between 0 and 5V. However, many of the packages commonly used in such applications are not rated for high voltages; for example, JEDEC standard 8 or 10 pin MSOPs are often rated for voltages less than 30V. Furthermore, under initial transient conditions, such as the starting of an automobile engine, voltage spikes can expose the pins to voltages even higher than those experienced during normal device operation.

Three significant problems can arise under such undesired conditions. First, the integrity of the signal frequencies carried by the pins can be severely degraded when the pins are too close to one another under high voltage conditions. Secondly, crosstalk can occur between two adjacent pins, especially when one or more of the pins are carrying a high voltage. Moreover, the two aforementioned problems may be further exaggerated in applications involving high frequency signals. Thirdly, since the pins are often plated with thin coatings of a lead/tin based solder, whiskering of the plating, otherwise known as dendrite growth, can occur between adjacent pins thereby corrupting the signals and/or rendering the device inoperative. In extreme cases, the whiskers can even create a short between adjacent pins. The whiskering issue is particularly relevant under high moisture levels, high temperatures and over extended periods of device operation.

A new package format is desired that mitigates the aforementioned problems in small-outline packages (SOPs) in high voltage/high frequency applications.

### SUMMARY OF THE INVENTION

To achieve the foregoing and other objects of the invention a novel molded, lead frame based integrated circuit package is described. The die has at least one high voltage I/O pad that is electrically connected to an associated lead/pin in the lead frame. The high voltage I/O pad is arranged to handle signals having voltages of at least 30 volts. By way of example voltages in the range of 30-100 volts are typical. All of the pins of the lead frame that are not high voltage pins have a standard pitch between adjacent pins on the same side of the lead frame that is no more than approximately 0.5 mm. The pitch between each high voltage pin and an adjacent pin is approximately double the standard pitch; that is, the spacing between the center of the high voltage pin and the center of an adjacent pin is approximately double the standard pin center to pin center spacing. With this arrangement, the gap between each high voltage pin in the lead frame and each adjacent pin is substantially equal to the width of one pin plus twice the standard gap between pins.

In some embodiments, the lead frame is formed from a copper or copper alloy based material and at least exposed portions of the pins are plated with a lead/tin based solder material.

In some described embodiments, the package is a dual inline package having a total of eight pins including two high voltage pins. In such embodiments, the package may generally conform to the footprint of a ten pin JEDEC standard package size. One such size is the ten pin MSOP package format.

The described package structure may be used in conjunction with a wide variety of high voltage/high frequency integrated circuits, such as those used in signal amplifications, wireless applications, and automotive systems such as engine control or GPS navigation systems.

### BRIEF DESCRIPTION OF THE DRAWINGS

The invention, together with further objects and advantages thereof, may best be understood by reference to the following description taken in conjunction with the accompanying drawings in which:

FIG. 1a is a diagrammatic top view of a leadframe strip or panel in accordance with the present invention;

FIG. 1b is a diagrammatic enlarged top view of the leadframe strip illustrated in FIG 1a showing a single column of device areas;

FIG. 1c is a diagrammatic enlarged top view of the leadframe that constitutes a single device area within the column of device areas illustrated in FIG. 1b;

FIG. 2a is a diagrammatic top view of a packaged integrated circuit that includes a leadframe as illustrated in FIG. 1c;

FIGS. 2b and 2c are diagrammatic side views of a packaged integrated circuit that includes a leadframe as illustrated in FIG. 1c;

FIG. 3a is a diagrammatic top view of a conventional MSOP package; and

FIGS. 3b and 3c are diagrammatic side views of a conventional MSOP package.

It is to be understood that, in the drawings, like reference numerals designate like structural elements. Also, it is understood that the depictions in the figures are diagrammatic and not to scale.

### DETAILED DESCRIPTION OF EXAMPLE EMBODIMENTS

In the following description, numerous specific details are set forth to provide a thorough understanding of the present invention. It will be apparent, however, to one skilled in the art that the present invention may be practiced without some or all of these specific details. In other instances, well known process steps have not been described in detail in order to avoid unnecessary obscuring of the present invention.

The present invention relates generally to the packaging of integrated circuits. More particularly, the invention relates to an integrated circuit package suitable for use in high voltage/high frequency applications requiring small-outline footprint packages. Such packages may additionally be lighter in weight than conventional packages, thereby further meeting the needs of denser module encapsulation. Such high voltage applications include signal amplifiers, wireless applications, and automotive systems such as engine control applications and GPS navigation systems. By way of example, in engine control applications, it is now common for a pin connected to a common mode voltage greater than 30V to be adjacent to a pin carrying a supply voltage between 0 and 5V. Furthermore, truck and electric car batteries often output even higher voltages. Moreover, under initial transient conditions, such as the starting of an automobile engine, voltage spikes can expose the pins to voltages even higher than those experienced during normal device operation. By way of example, it is common for a truck battery to output 42V during operation; however, during ignition voltage spikes can reach 60V.

Additionally, wireless and satellite communication applications may subject IC devices to high frequencies as well as high voltages. By way of example, many telecom applications subject devices to voltage signals having frequencies in the range of approximately 1.1 to 1.6 GHz. Device operation under such high frequencies is very sensitive to noise, specifically crosstalk, such as that which can be produced as a result of electrical interference when pins are positioned too close to one another in an IC package.

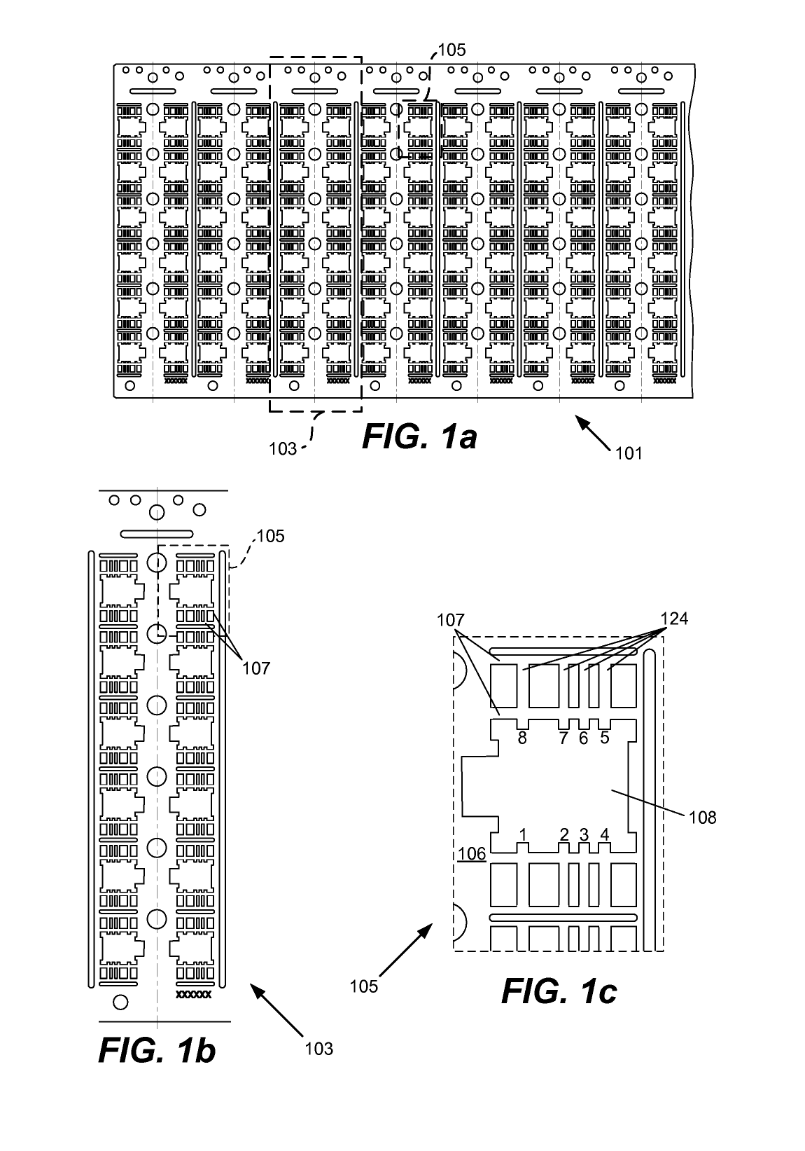

Referring initially to FIGS. 1a-1c, a lead frame design in accordance with various embodiments of the present invention will be described. FIG. 1a is a diagrammatic top view of a lead-frame strip suitable for use in packaging integrated circuits. A lead-frame strip (panel) 101 is formed from a suitable conductive material. Typically the lead frame strip is formed from a metallic material such as copper, copper alloy, aluminum, etc., although other materials may also be suitable and used instead or in combination. In the illustrated embodiment, the leadframe strip 101 has a number of sections 103 that each includes a two-dimensional array of device areas 105. Each device area 105 is configured for use as a leadframe 106 in a single SOP package. FIGS. 1b and 1c successively illustrate more details of the lead frame strip 101. More specifically, FIG. 1b illustrates the single section 103 that includes the two dimensional array of device areas 105. A web of metallic supports, including tie bars 107, hold the leadframe panel together.

FIG. 1c illustrates details of the leadframe 106 associated with a single device area 105. As better seen in FIG. 1c, each device area 105 has a number of contact pins 124 and an associated die attach area 108. The contact pins 124 are supported at both ends by the tie bars 107. In other embodiments, the leadframe can include a die attach pad or other such die support structure located within the die attach area 108.

In the described embodiment, the leadframe is suitable for use in a DIP package, and specifically, a standard ten pin MSOP package having a pitch that is no more than approximately 0.5 mm, although the present invention can be practiced on other SOP packages, including small quad flat pack (QFP) packages, quad flat pack no leads (QFN) packages, etc. Of course, the invention can be practiced on packages that have virtually any pin count, however, it is particularly applicable to packages having pin pitches of 0.5 mm or less.

In the embodiments described herein, the dice to be packaged are designed for use in high voltage/high frequency applications. Each die has at least one I/O pad designated for use as a high voltage I/O pad that is arranged to transmit signals having voltages in the range of approximately 30 volts to 120 volts (or greater). The subsequent description will focus on dice having two such high voltage I/O pads. According to embodiments of the present invention, the leadframe device area 105 is stamped such that all of the pins of the leadframe that are not designated as high voltage pins have a standard pitch between adjacent pins on the same side of the leadframe that is no more than approximately 0.5 mm. The pitch between each high voltage pin, labeled as pins 1 and 8 in the illustrated embodiment, and an adjacent pin is approximately double (or greater) the standard pitch; that is, the spacing between the center of the high voltage pin and the center of an adjacent pin is approximately double the standard pin center to pin center spacing, as shown in FIG. 1c. With this arrangement, the gap between each high voltage pin in the lead frame and each adjacent pin is substantially equal to the width of one pin plus twice the standard gap between pins.

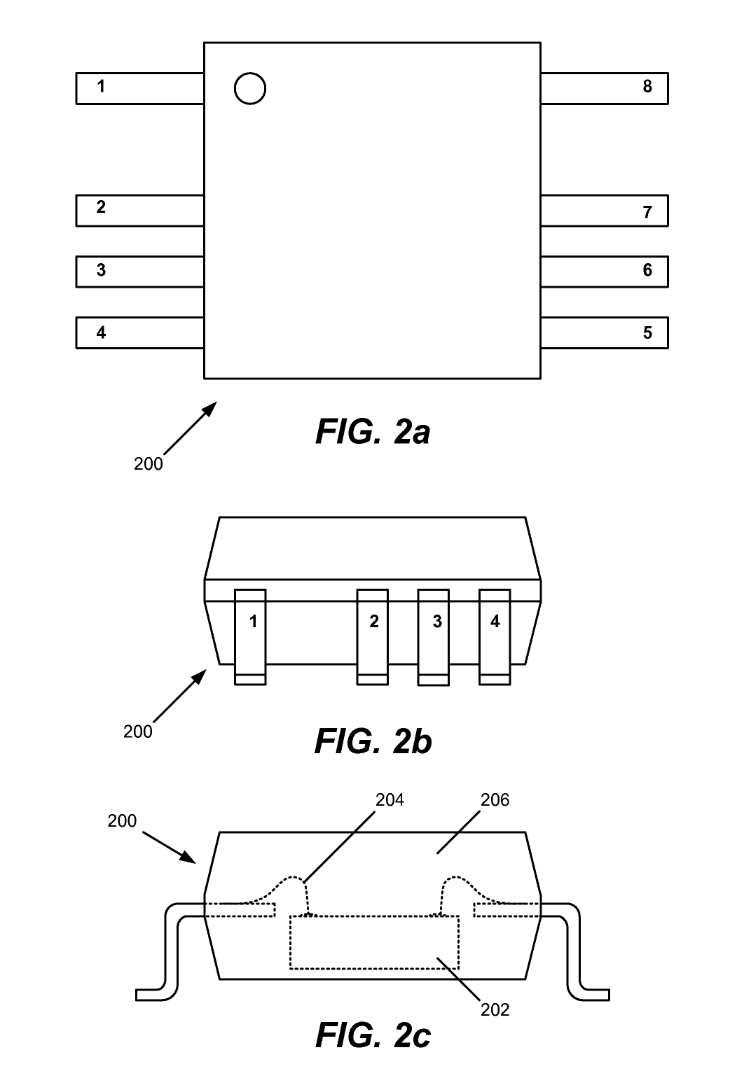

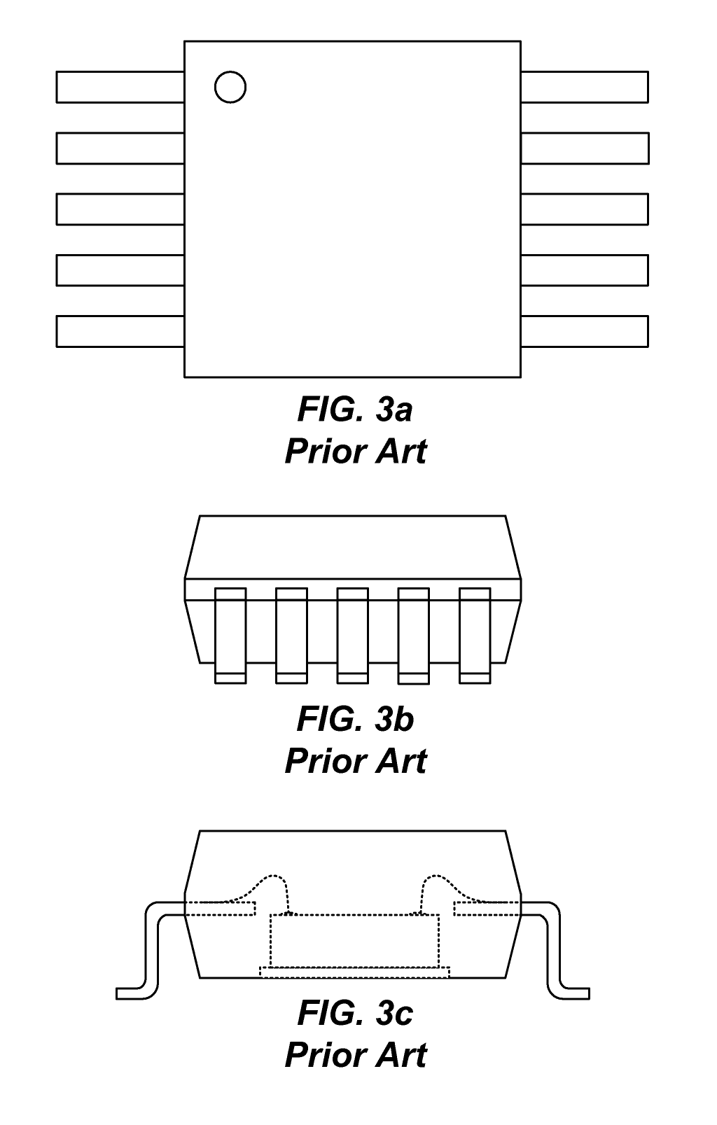

Referring next to FIGS. 2a-c, an eight pin integrated circuit package 200 having a ten pin footprint is described which incorporates the aforementioned leadframe illustrated in FIG. 1c. In the illustrated embodiment, pins 1 and 8 are designated as high voltage pins. The I/O pads on the die 202 are electrically connected to associated pins 1-8 on the leadframe 106 via bonding wires 204. A molding material is used to encapsulate the device area leaving portions of the pins exposed on two sides of the mold 206. The exposed portions of the pins may then be bent into the “gull wing” shape suitable for use in surface mounting applications. The resultant package 200 is an eight pin MSOP package having a ten pin MSOP package footprint. Additionally, the exposed portions of the pins may be plated with a lead/tin based solder material.

It should be noted that in other embodiments, such as in QFN packages, the contacts may be left exposed only on the bottom surface of the package.

The extra spacing around the high voltage pins significantly reduces the electric field in between the high voltage pins and their neighboring pins thus reducing interference between pins as well as significantly inhibiting the growth of tin whiskers in between pins.

Although only a few embodiments of the invention have been described in detail, it should be appreciated that the invention may be implemented in many other forms without departing from the spirit or scope of the invention. For example, the described engine control applications tend to have input/output voltages in the range of 30 to 100 volt. There are a wide variety of devices that are designed to operate at standard A/C voltages (e.g., 100 volts, 120 volts, 220 volts, etc.) and the described packages work well for these applications as well. Therefore, the present embodiments are to be considered as illustrative and not restrictive and the invention is not to be limited to the details given herein, but may be modified within the scope and equivalents of the appended claims.

What is claimed is:

1. An integrated circuit package comprising:
a lead frame having a plurality of pins including at least a first pin designated as a high voltage pin, wherein all of the pins of the lead frame that are not high voltage pins have a standard pitch between adjacent non-high voltage pins on the same side of the lead frame that is no more than approximately 0.5 mm, and wherein the pitch between each high voltage pin and an adjacent pin is substantially double the standard pitch;
an integrated circuit die including a plurality of I/O pads that are electrically connected to associated pins, wherein at least one of the I/O pads is designated as a high voltage I/O pad, each high voltage I/O pad being electrically connected to an associated high voltage pin; and
a molding material that encapsulates at least portions of the die and the lead frame while leaving portions of the pins exposed to facilitate electrical connection to an external device.

2. An integrated circuit package as recited in claim 1 wherein the lead frame is formed from a copper or copper alloy based material and wherein at least exposed portions of the pins are plated with a lead/tin based solder material.

3. An integrated circuit package as recited in claim 1, wherein the package is a dual inline package (DIP).

4. An integrated circuit package as recited in claim 3 wherein the package has a total of eight pins including two high voltage pins, and the package generally conforms to a ten pin JEDEC standard package size.

5. An integrated circuit package as recited in claim 4 wherein the package generally conforms to a ten pin MSOP package footprint.

6. An integrated circuit package as recited in claim 1 wherein the package generally conforms to a ten pin MSOP package footprint.

7. An integrated circuit package as recited in claim 1 wherein the integrated circuit package is a component of one of a group including: an engine control unit, a GPS navigation system, a signal amplifier, or a telecom device.

8. An integrated circuit package as recited in claim 1 wherein the integrated circuit die is arranged to transmit signals having frequency components of at least 1 GHz from the high voltage I/O pad.

9. An integrated circuit package as recited in claim 8, wherein the integrated circuit die is arranged to transmit signals having frequency components in the range of approximately 1.1 to 1.6 GHz from the high voltage I/O pad.

10. An integrated circuit package as recited in claim 1 comprising a plurality of high voltage I/O pads and a plurality of high voltage pins.

11. An integrated circuit package as recited in claim 10 wherein two high voltage I/O pads and two high voltage pins are provided, the high voltage pins being positioned across from one another on opposing sides of the package on a first end of the package.

12. An integrated circuit package as recited in claim 1, wherein the package is a quad flat pack package (QFP) or a quad flat pack no leads package (QFN).

13. An integrated circuit package as recited in claim 1, wherein the pitch between each high voltage pin and an adjacent pin is greater than double the standard pitch.

14. An integrated circuit package as recited in claim 1, wherein the high voltage pins and non-high voltage pins have substantially equal width and each high voltage pin in the lead frame is separated from each adjacent pin by approximately the width of a pin plus twice the distance that adjacent pins that are not high voltage pins are separated from one another.

15. An integrated circuit package as recited in claim 1, wherein each high voltage I/O pad is arranged to transmit signals having voltages of at least 30 volts.

16. An integrated circuit package comprising:
a lead frame having a plurality of pins including two pins designated as a high voltage pins, wherein all of the pins of the lead frame that are not high voltage pins have a standard pitch between adjacent non-high voltage pins on the same side of the lead frame that is no more than approximately 0.5 mm, and wherein the pitch between each high voltage pin and an adjacent pin is approximately double the standard pitch, whereby each high voltage pin in the lead frame is separated from each adjacent pin by approximately the width of a pin plus twice the distance that adjacent pins that are not high voltage pins are separated from one another, the lead frame being formed from a copper or copper alloy based material and wherein at least exposed portions of the pins are plated with a lead/tin based solder material, the high voltage pins being positioned across from one another on opposing sides of the package on a first end of the package;
an integrated circuit die including a plurality of I/O pads that are electrically connected to associated pins, wherein two of the I/O pads are designated as high voltage I/O pads that are arranged to transmit signals having voltages of at least 30 volts, each high voltage I/O pad being electrically connected to an associated high voltage pin; and
a molding material that encapsulates at least portions of the die and the lead frame while leaving portions of the pins exposed to facilitate electrical connection to an external device; and
wherein the package has a total of eight pins including two high voltage pins, and the package generally conforms to a ten pin JEDEC standard package size.
